(19) United States
(12) Patent Application Publication
(10) Pub. No.: US 2006/0170081 A1
(43) Pub. Date: Aug. 3, 2006

(54) Method and apparatus for packaging an electronic chip

(76) Inventors: Mark Allen Gerber, Plano, TX (US); Takahiko Kudoh, Beppu-city (JP); Mutsumi Masamoto, Beppu-city (JP); Alejandro Hernandez-Luna, Dallas, TX (US)

Correspondence Address: TEXAS INSTRUMENTS INCORPORATED, P O BOX 655474, M/S 3999, DALLAS, TX, 75265, US

(21) Appl. No.: 11/050,086

(22) Filed: Feb. 3, 2005

(51) Int. Cl. H01L 23/495

(52) U.S. Cl. 257/666

(57) ABSTRACT

An electronic packaging combines features of a MAP (molded array package) and a lead frame package. The package includes an electrically conductive substrate somewhat like a lead frame package but defines a grid of conductive pads rather than a multiplicity of leads as is common with a lead frame package. An electronic chip is attached to the top surface of the lead frame, and the output terminals of the electronic chip are individually electrically connected to selected connecting pads of the lead frame grid array. Both flip chips and wire bond chips may be connected to the grid array. The channels defining the grid of connecting pads extend part way through the conductive substrate and increase in width from the top surface of the lead frame to the bottom of the channel such that the molding compound is locked in place when it cures and hardens. The grid pads are then singulated by sawing or etching channels from the bottom surface of the lead frame substrate that correspond to the channels defining the connecting pads on the top surface.

### TECHNICAL FIELD

The present invention relates generally to integrated circuit chip package technology and more particular to a package that advantageously combines lead frame technology and MAP (mold array package) technology.

### BACKGROUND

Integrated circuit dies are conventionally enclosed in plastic packages that provide protection from hostile environments and enable electrical interconnection between the integrated circuit die and an underlying substrate such as a printed circuit board. The elements of such a package include a metal lead frame, an integrated circuit die, bonding material to attach the integrated circuit die to the lead frame, bond wires, which electrically connect the pads on the integrated circuit die to individual leads of the lead frame, and a hard plastic encapsulant material which covers the components and forms the exterior of the package.

The lead frame is the central supporting structure of the package and a portion of the lead frame is internal to the package. That is, portions of the lead frame are completely surrounded by the plastic encapsulant. Portions of the leads of the lead frame externally from the plastic encapsulant or are partially exposed within the encapsulant material for use in electrically connecting the chip package to another component or to the printed circuit board.

For purposes of high volume, low cost production, a current technique is to etch or stamp a thin sheet of metal material to form a panel or strip, which defines multiple lead frames. A single panel or strip may be formed to include multiple arrays with each array including a multiplicity of lead frames according to a particular pattern. In a typical semiconductor package manufacturing process, a multiplicity of integrated circuit dies are mounted and wire bonded to respective ones of the lead frames on the strip, the encapsulant material is then applied to the strips so as to encapsulate the integrated circuit dies, bond wires, and portions of each of the lead frames as described above. As will be appreciated by those skilled in this art, laminate tape may be used to protect the bottom of the lead frame during the mold process. Alternatively, a soft mold may be used on the bottom of the tool to form a seal around the fingers of the lead frame.

After hardening of the encapsulant material, the lead frames on the strip, and within the encapsulant are then cut apart or singulated for purposes of producing the individual semiconductor packages. Such singulation is typically accomplished via a sawing process wherein a saw blade is used to form a channel or kerf between the individual lead frames such that the saw kerf facilitates the separation of lead frames from each other.

However, pricing pressures in the assembly of integrated circuits have encouraged the development of alternate array packaging solutions. As an example, Ball Grid Array (BGA) packages provide advantages such as total input/output count and package body size over lead frame based packages. Thus, more and more new IC's are being packaged in an organic BGA type packaging solution. However, as will be appreciated, almost every new solution has its own problems and disadvantages. For example, the disadvantages of the BGA packaging compared to lead frame based packages include: higher input/output conductance, poor thermal performance, and usually higher cost.

Therefore, a packaging solution that could incorporate the advantages of both the mold array package and the lead frame package would be beneficial.

### SUMMARY OF THE INVENTION

Accordingly, the present invention provides methods and structure comprising a conductive grid frame having a selected size and comprising an upper portion with a top surface, an intermediate portion, and a bottom portion. The grid frame is similar to a lead frame formed on a strip, and is also similar to a MAP strip design. However, the grid frame will be made from a lead frame alloy and will incorporate the grid pattern in the lead frame design for die positioning and attaching wire bonds. Further, since the lead frame strip is solid, a bottom tape lamination or soft mold die is not required to protect the bottom contact of the grid frame. The upper portion of the grid frame defines channels extending from the top surface toward the bottom of the channel in an intermediate portion of the grid frame so as to form a multiplicity of terminal pads. Therefore, the defined channels are more narrow at the top surface than at the bottom of the channel. When a molding compound is deposited over the package and allowed to cure or harden, the cured material is inter locked with the lead frame, because of the narrow channel width at the top surface of the frame. The electronic chip includes a plurality of connecting points and can be either a wire bond chip or a flip chip. In the case of a wire bond chip, the connecting points on the chip are connected to selected ones of the terminal pads by wire conductors bonded between the terminal pads and the connecting points. For a flip chip, the soldered balls on the bottom side of the flip chip are arranged to correspond to selected ones of the terminal pads. After the solder balls of the electronic chip are bonded into place so as to make electrical connections between the electronic chip circuits and the terminal pads, the molding material is deposited over the electronic chip and the grid frame so as to fill the channels defined in the lead frame. A multiplicity of singulation channels are then defined in the bottom portion of the grid frame and extend from the bottom portion toward the intermediate portion to complete the electrical isolation between the terminal pads. The singulation channels may be either formed in the bottom of the grid frame by sawing, grinding or by etching. It will, of course, be appreciated that the singulation channels will correspond to or be in register with the channels in the upper portion of the grid frame, which define the terminal pads.

It should also be appreciated, that more than one electronic chip may be located on the grid frame such that two electronic chips are included in the package. Further, one or more surface mounted discreet devices may also be connected between selected ones of the terminal pads.

It will also be appreciated, that a rectangular (including square) electronic chip may be located such that two or more rows of terminal pads may exist on one or more of the four sides of a rectangular shaped electronic chip. Further, when the electronic chip is a flip chip, and the connection points are solder bumps, selected ones of the terminal pads may define divots for accurately locating the electronic chip on the grid frame. In addition, to aid in heat removal of a package, a flip chip may also include a heat conductive layer on its top surface, which includes heat conductive legs extending from the heat conductive layer to selected perimeter pads of the terminal pads so as to help remove heat from the array package.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 is a top view of a grid frame strip design according to the present invention;

FIGS. 2A and 2B represent enlarged portions of the grid frame strip of FIG. 1 and illustrate how various chips of different dimensions and having a different number of output connectors may be used with the same grid frame strip design;

FIG. 3A shows the layout for placing 16 lead frames on an 88×27 grid frame strip, and FIG. 3B illustrates locator tic marks for placements of the die;

FIGS. 4A and 4B show a perspective view and a partial cross-sectional view of the grid frame according to the present invention;

FIGS. 5A through 5E illustrate an example of the grid frame of the present invention and the attachment of discreet devices onto a wire bond chip;

FIGS. 6A and 6B illustrate singulation of the chip by sawing the bottom side of the grid frame;

FIG. 7 is a cross sectional view of a grid frame package according to the present invention wherein singulation is accomplished by grinding;

FIGS. 8A, 8B, and 8C illustrates various examples of a grid frame package according to the present invention including two chips, two discrete devices and a raised discrete device to eliminate damage due to the sawing process;

FIG. 9 illustrates a cross sectional view of a flip chip used with a grid frame according to the present invention;

FIGS. 10A, 10B, and 10C illustrate the manufacturing process of a chip package according to the present invention wherein the electronic chip is a flip chip;

FIG. 11 illustrates the detail of the solder ball connection according to another embodiment of the invention and the singulation channels; and

FIG. 12 illustrates a flip chip heat sync with heat conductive legs.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

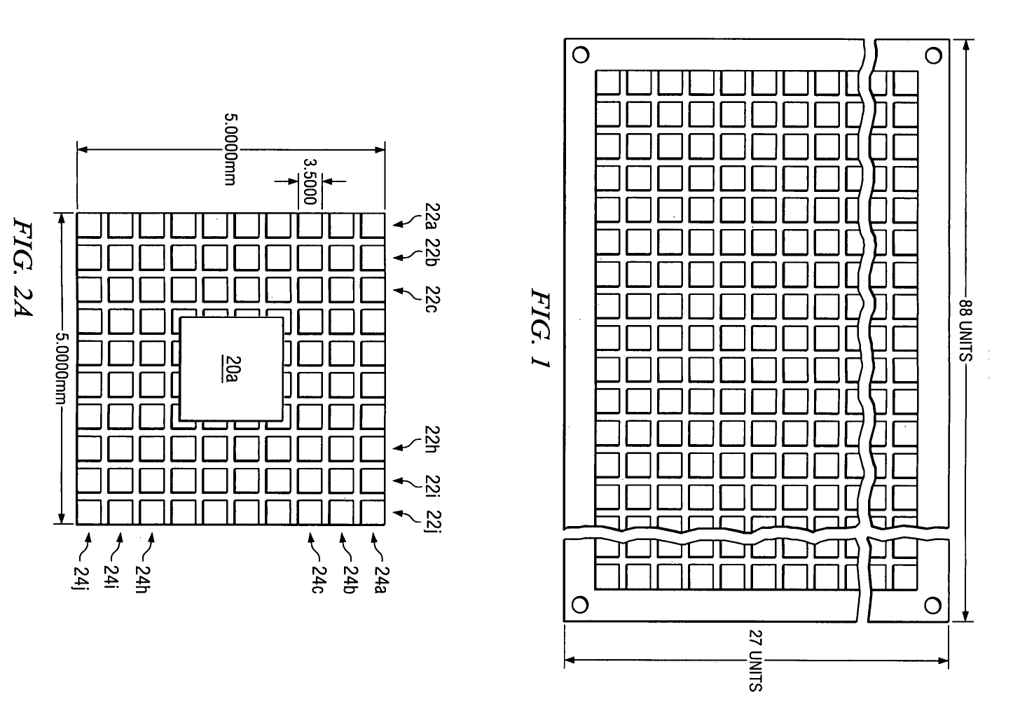

Referring now to FIG. 1, there is shown as an example a grid frame strip design according to the teachings of the present invention. As shown, the grid frame may be either a stamped or etched sheet of conductive material, such as copper or a copper alloy, and may also be pre-plated to allow for effective wire bonding. As will be discussed below, a grid may be etched in the grid frame substrate or alternately, several passes with a thin saw can produce a combination of saw kerfs that can be used to form the grids. In any event, and as will be discussed in detail hereinafter, the channels are formed in a grid, and the channels forming the individual grids are more narrow at the top surface of the grid frame then at the bottom of the channels. Further as will be discussed hereinafter, by having the channels increase in width as they extend from the top surface of the grid frame to the bottom of the channels, the cured molding compound (to be discussed hereinafter) and the grid frame will be interlocked.

It should further be appreciated by those skilled in the art, that the size of the grid frame as well as the pitch of the grid may vary depending upon the different requirements. Typically the grid pitch will be selected at a 0.5, a 0.65, a 0.8, or a 1.0 mm dimension.

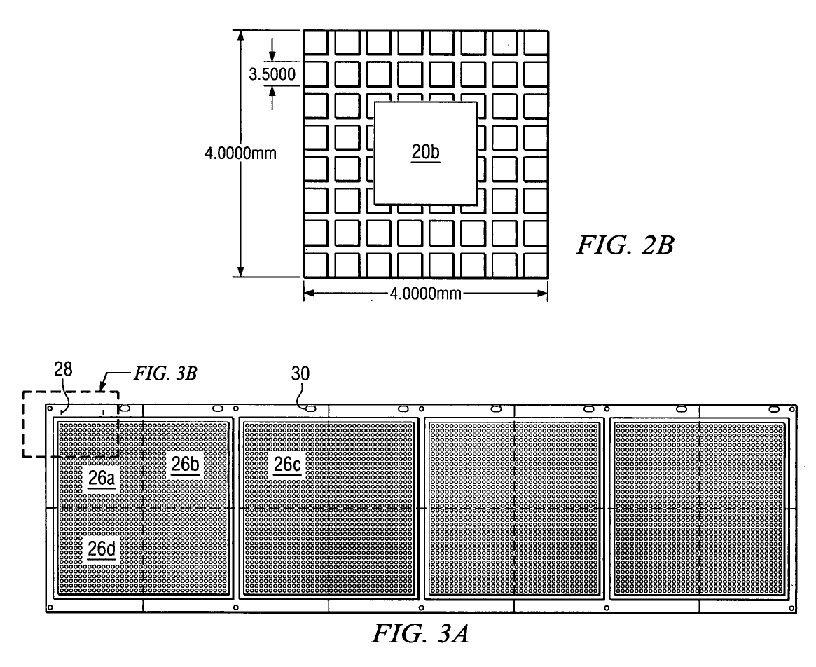

For example, the grid frame strip design of FIG. 1 illustrates a grid frame 88 units long and 27 units wide, and includes grids having a pitch of 0.5 mm. However, it should be appreciated that the grid frame of FIG. 1 is an example only, and that both the grid frame length and width could be selected and or designed to have a greater number or lesser number of units. The example of FIG. 2A illustrates how a wire bond chip 20a having a die of approximately 1.6 by 1.5 mm may be located or positioned to cover an area comprising 16 terminal pads (4×4) such that three rows 22a, 22b, and 22c and 22h, 22i, and 22j of terminal pads are available for use on either side of the electronic chip 20a. Likewise, horizontal rows 24a, 24b, 24c, and 24h, 24i, and 24j are available for use on the other two sides of the chip 20a. Thus, for a portion of the grid having a size of 10 units by 10 units, eighty-four terminal pad connections are available for use with chip 20a of FIG. 2A. Therefore, it will be appreciated that if a grid frame array is formed from the grid frame strip shown in FIG. 1 (i.e., 27 units wide and 88 units long), the grid frame strip may be used to provide grid frames for 16 individual electronic chips of the type illustrated in FIG. 2A. Again, however as mentioned above, the grid frame strip could be selected to have a length greater than 88 units (or less), and a width greater (or less) than 27 units.

Similarly, a 1.965 mm. square electronic chip 20b, as shown in FIG. 2B, could be mounted in an area of the grid frame strip of FIG. 1 comprising 8 grid units by 8 grid units. In this embodiment, two rows of terminal pads will be available on each of the four sides of the electronic chip 20b such that a total of 48 terminal pads will be available for connecting each chip. Thus, 27 grid frame packages of the type illustrated in FIG. 2B may be obtained from the 27 by 88 grid frame strip design example illustrated in FIG. 1.

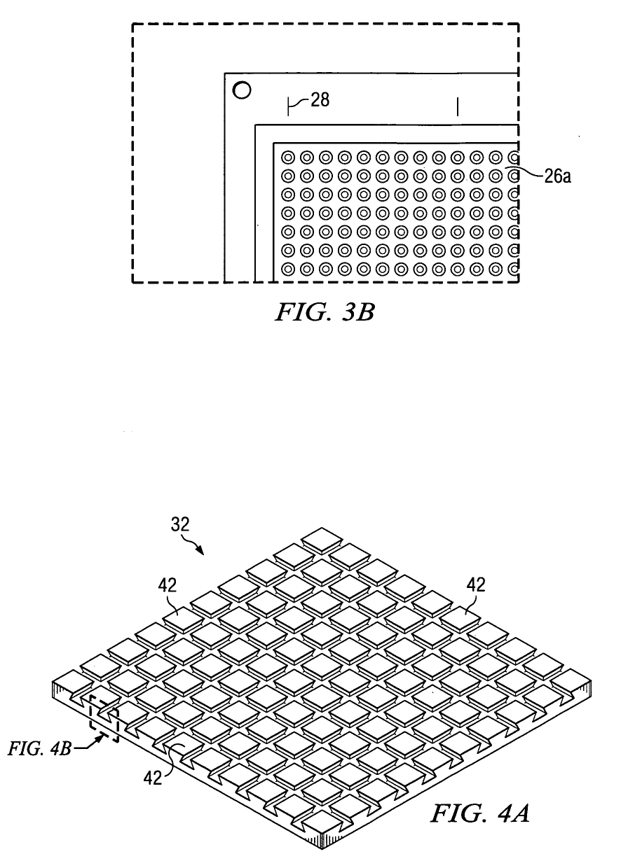

Referring now to FIG. 3A there is another view of the 27×88 grid frame strip example of FIG. 1 that illustrates the flexibility of the present invention. This view of FIG. 3A illustrates the layout for providing 16 individual chips, such as for example chips, 26a, 26b, 26c and 26d. FIG. 3B is an enlarged view of the upper left hand corner section of FIG. 3A that includes the lead frame 26A. Tic marks such as Tic marks 28 and 30 are used to locate areas of the grid frame strips for proper alignment for die placement and separating the strips into individual lead frames.

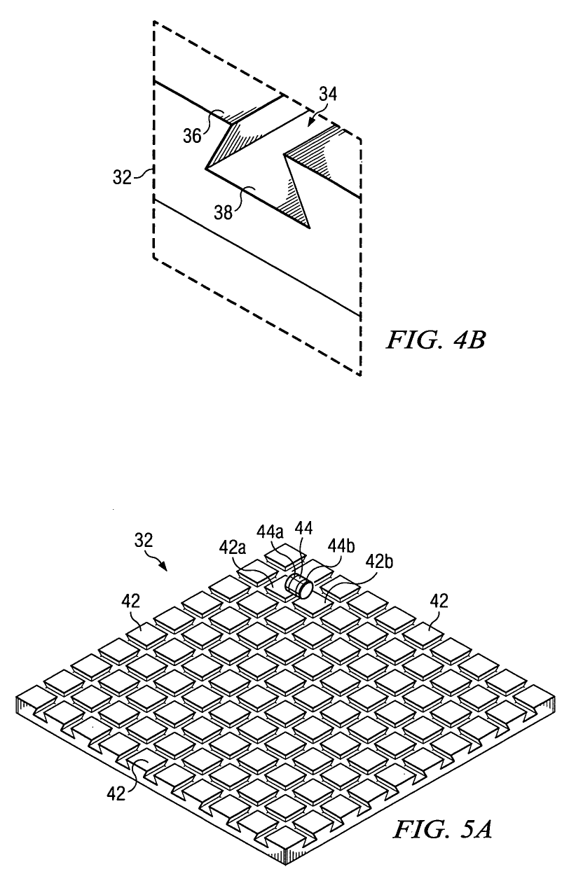

Referring now to FIG. 4A, there is shown a perspective view of a grid frame substrate 32 having a 10 by 10 grid pattern such as discussed with respect to FIG. 2A. The 10×10 grid pattern of FIG. 4A could represent a portion of a 27×88 unit grid frame strip or a portion of a grid frame strip of any selected size. FIG. 4B is an enlarged view that illustrates how the width of the channels that define the individual terminal pads, such as channel 34 is smaller or more narrow at the top surface 36 than it is at the bottom surface 38. The bottom surface of the channel 34 is located approximately in the middle or the intermediate portion of the grid frame substrate 32. The grid frame substrate 32 will be discussed as having a top portion, an intermediate portion, and a bottom portion.

Although any suitable technique for providing the channel 34 so that the channel width is smaller at the top than it is at the bottom 38 of the channel may be used, one effective technique is by isotropic etching. Alternately, several passes at different angles of a thin saw blade could be used.

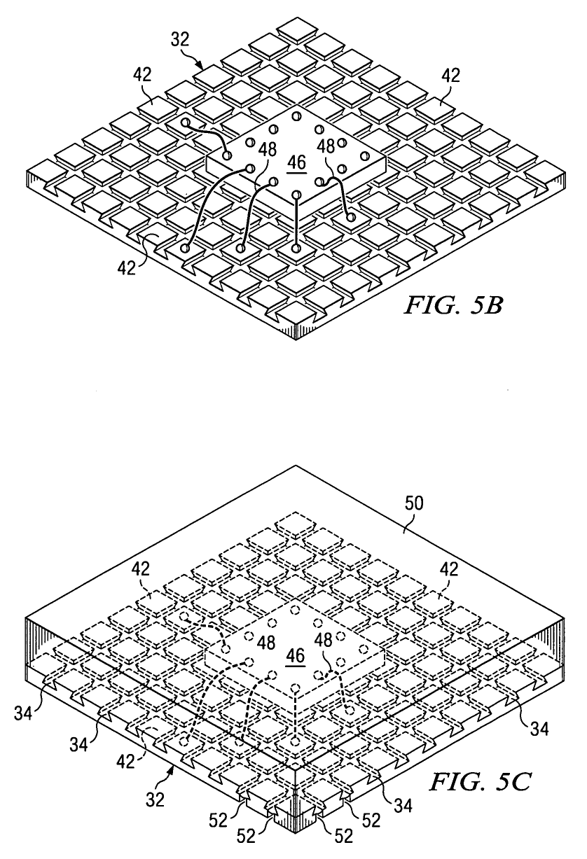

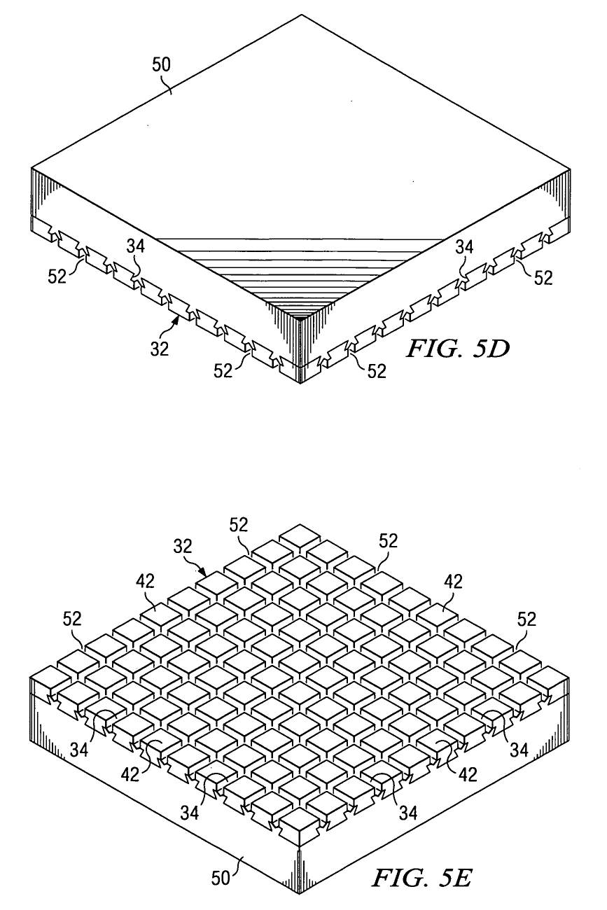

Referring now to FIGS. 5A through 5D, there are shown a sequence of figures illustrating the method of the present invention. FIG. 5A is similar to FIG. 4 as discussed above, except that the grid frame 32 with 100 defined terminal pads 42 (i.e. 10×10) further includes a surface mounted discreet device 44, such as for example a capacitor or a resistor, having conductive ends 44a and 44b directly soldered between two of the terminal pads 42a and 42b. Alternately, connecting wires could be added between the terminal pads and the conductive ends. It will be appreciated of course that the mounting of a surface mounted discreet device 44 is optional. Therefore, referring now to FIG. 5B, there is shown a wire bond chip 46 located on the grid frame 32 such that three rows of terminal pads exist on each side of wire bond chip 46. Examples of wire bond connections 48 from the wire bond chip 46 to terminal pads 42 are also illustrated in FIG. 5B. Although only 5 wire bond connections are shown, it will be appreciated that all 84 terminal pads 32 not covered by chip 46 are available for a connection.

FIG. 5C illustrates how the molding compound 50 is then formed over the wire bond chip 46, the conductors 48 connecting the wire bond chip, the terminal pads 42 including the terminal pads unused by the chip 46, and the substrate 32. It is important to note that the molding compound also flows into the dovetailed channels 34 formed in substrate 32 and is locked in place when the molding compound cures and hardens. FIG. 5C also shows how channels, such as the four channels 52, may be cut or etched in the bottom surface of the grid frame 32. Channels 52 are aligned with the channels 34 formed in the top portion of the grid frame such that they completely separate and electrically isolate the 100 terminal pads of the package. FIG. 5D illustrates the completed package with all channels 52 cut through the lead frame 32, and FIG. 5E is a bottom view of FIG. 5D showing all of the singulated individual terminal pads of the completed package.

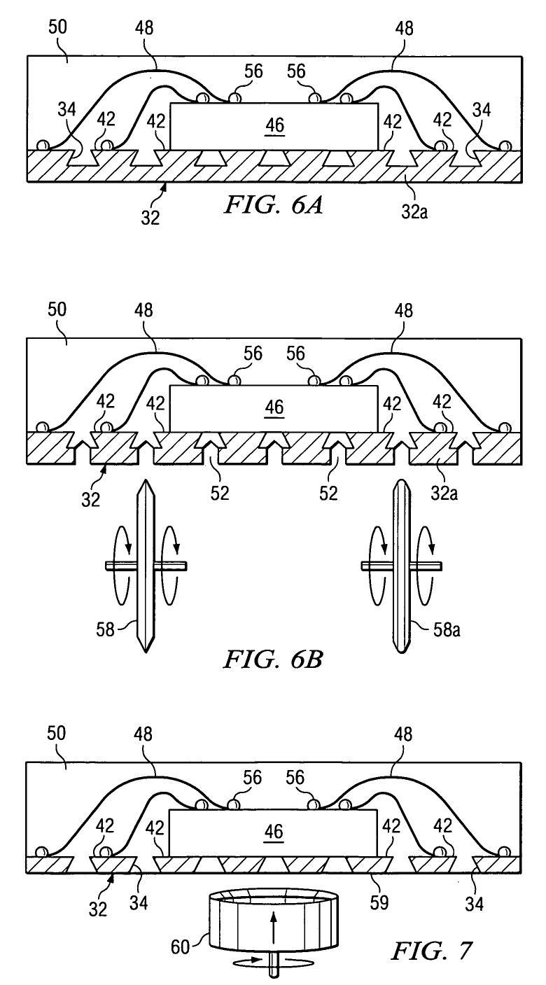

More specifically, referring to FIGS. 6A and 6B there is a more detailed cross-sectional view of the chip and 8×8 grid frame assembly of FIG. 2B. As shown, conductors 48 are connected between individual terminal pads 42 to connection points 56 on the top surface of wire bond chip 46. In the illustrated view it is seen that a bottom portion 32a of the lead frame is a unitary solid piece of conductive material such as copper or a copper alloy. Therefore, it should be appreciated that the various individual terminal pads 42 are still all electrically connected together. Therefore, referring to FIG. 6B, there is illustrated the process of singulating or dividing the individual terminal pads 42 by means of forming bottom channels 52 which correspond to or are in register with the channels 34 on the top surface of the grid frame 32 that define the individual terminal pads 42. Thus, it is seen that saw blade 58 cuts completely through the bottom portion 32a of the grid frame to separate the individual terminal pads 42. Although various shapes of saw blades could be used to form the bottom grid of channels for separating the terminal pads, those skilled in the art will appreciate that it may be important to consider the shape of the saw blade so as to reduce stresses in the finished package. For example, saw blade 58a has a rounded cutting edge.

Referring to FIG. 7 there is shown another embodiment for dividing or separating the individual terminal pads 34. According to the embodiment FIG. 7 the bottom surface 32a may be ground or abraded by wheel 60 to remove material until the channels formed in the top portion of the grid frame 32 are reached. To limit the amount of material that must be removed, the grid channels formed in the top portion may preferably extend deeper into the lead frame. After sufficient material has been removed to singulate the individual terminal pads of the grid frame, it may be desirable to provide an alloy plating 59 on the bottom surface.

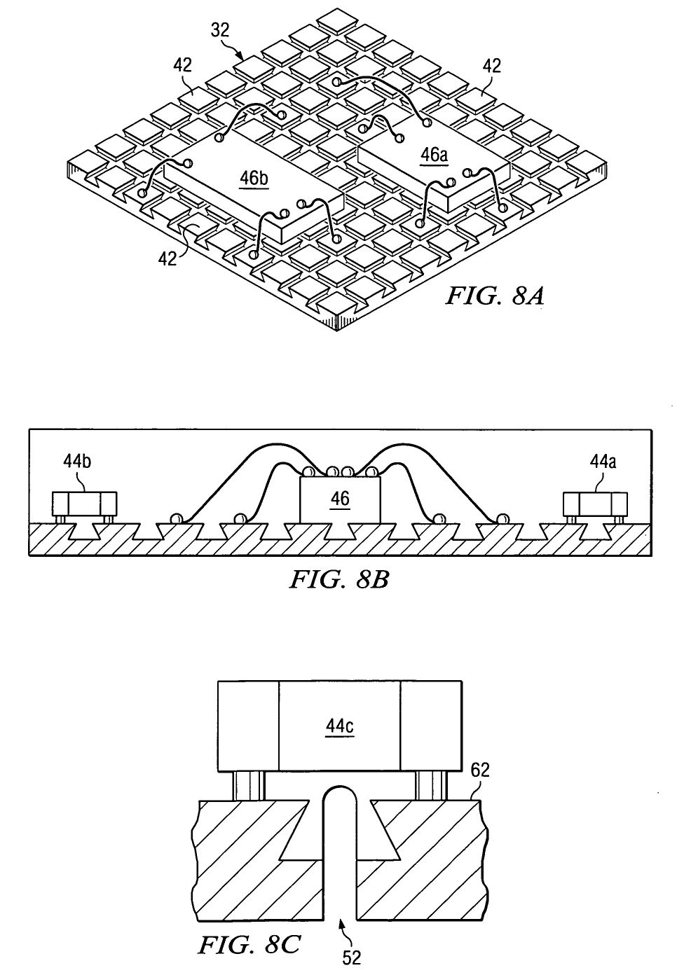

FIGS. 8A, 8B, and 8C are similar to the device of FIG. 6A except FIG. 8A includes two different chips 46a and 46b, and FIGS. 8B and 8C includes two discrete surface mounted devices 44a and 44b in addition to chip 46 as discussed above. FIG. 8C illustrates that it may be desirable to raise the discrete device 44c above the top surface 62 of the grid frame substrate so as to prevent possible damage from the saw cut 52 going too deep into the molding material.

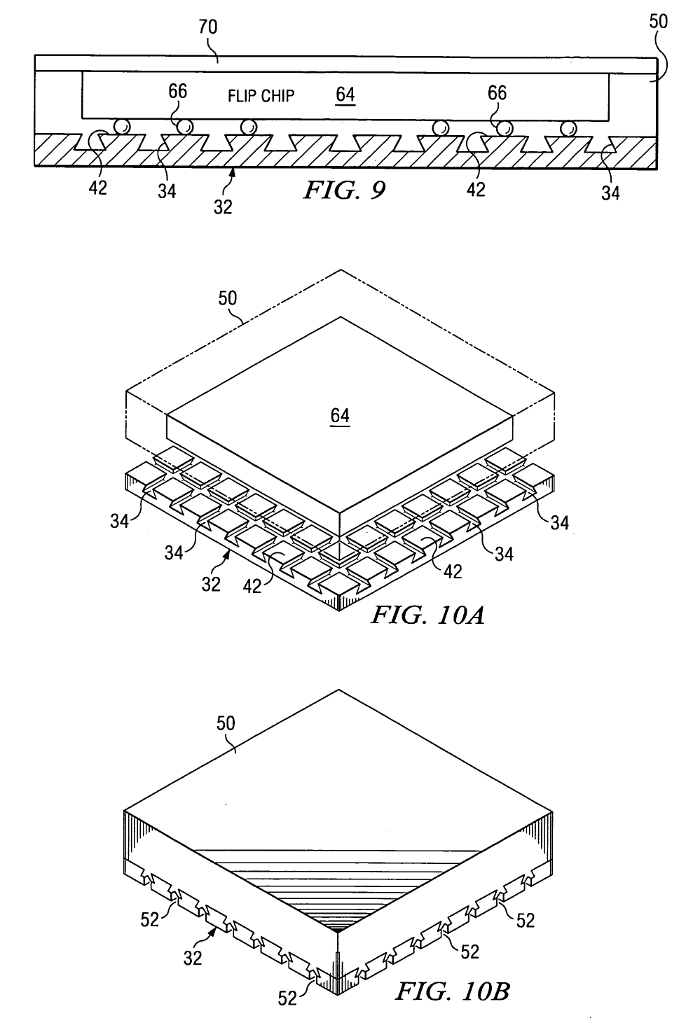

As will be appreciated by those skilled in the art, the previous discussion was with respect to connecting and forming an electronic package wherein the electronic chip was a wire bond chip. As will be appreciated, the present invention may also be advanteously used with respect to a flip chip. Therefore, referring to FIG. 9 there is shown a cross sectional view of a package according to the present invention that comprises a simplified example of a flip chip 64 having solder ball connections 66 mounted to the terminal pads 42 formed on the grid frame 32. A molding material 50 interlocks with the channels 34 cut in the grid frame 32 and encapsulates the flip chip 64.

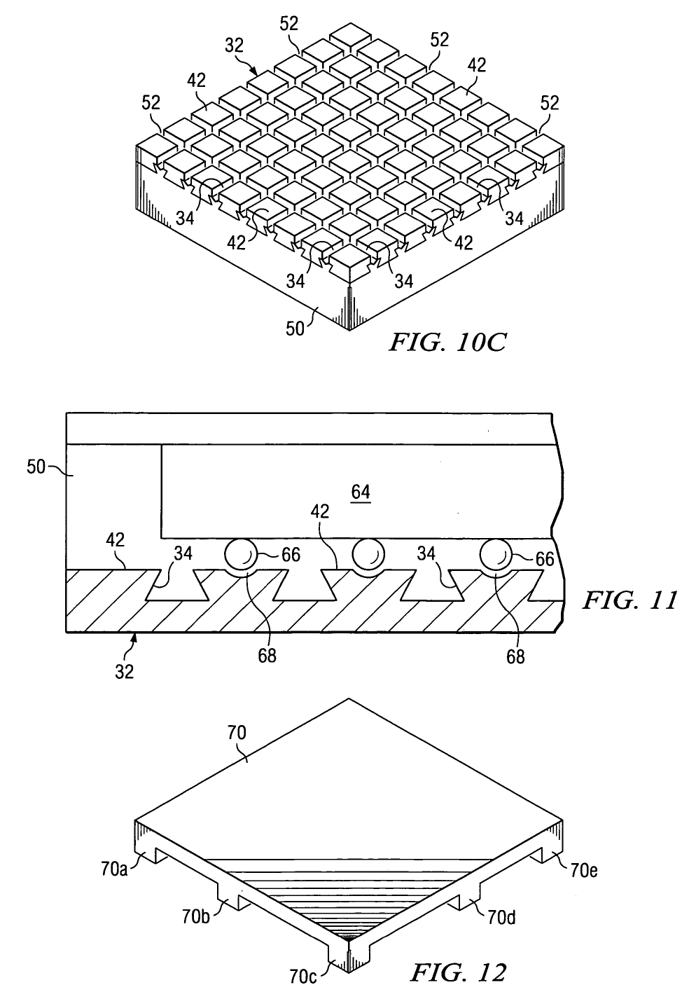

FIGS. 10A through 10C illustrate how the flip chip 64 is mounted to the top surface of the grid frame array 32 of terminal pads 42 according to the present invention. Connecting the solder ball connections 66 to the terminal pads 42 is achieved in a typical manner of heating the flip chip structure until the solder balls 66 soften and bond the chip 64 to the lead frame 32. However after the flip chip 64 is positioned and bonded and the electrical connections made, the process according to the present convention is similar to that discussed above with respect to wire bond chips. Thus, there is included a layer of molding compound 50 around the flip chip 64 and the grid frame 32 in the same manner as was discussed above. Also, as was the case as discussed above with respect to the wire bond chips, the channels defining the individual terminal pads used as connections to the solder ball connections are more narrow at the top then they are at the bottom of the channel. Therefore, the liquid compound will fill the channels and, when cured, will be locked into place with respect to the grid frame 32 thereby providing a sturdy and robust package. Then as was discussed above with respect to the wire bond package, the terminal pads are singulated by providing saw kerfs 52 through the bottom portion 32a of the grid frame that correspond to and are in register with the channels 34 formed in the top portion. It will also be appreciated, of course, that as was discussed above an etching technique may be used to achieve the singulation rather than using a saw. A bottom view of the final product then is illustrated in FIG 10C.

According to another embodiment of the invention illustrated in FIG. 11, the surface of the individual terminal pads 42 that are positioned to receive the solder ball connections 66 of the flip chip 64 may define a divot 68 in one or more of the terminal pads so as to capture and help align the flip chip 64 in the proper location on the grid frame 32.

Referring again to FIG. 9 and to FIG. 12, there is shown still another embodiment of the present invention particularly applicable to the flip chip 64 package. As was discussed above, a disadvantage of the ball grid array type packaging is the poor thermal performance and the problem of removing heat from the flip chip. The present invention provides a unique opportunity for achieving effective heat removal from the flip chip. Referring to FIG. 12, there is shown a heat sink 70 (typically made from aluminum, copper or other heat conductive metal) for use of the flip chip including heat conductive legs 70a, 70b, 70c, 70d and 70e. The heat sink 70 is bonded to the top surface of the flip chip 64 and the individual heat conductive legs are each bonded to one of the perimeter terminal pads 42 such that an excellent heat path exists from the top surface of the flip chip through the conductive layer or heat sink 70 bonded to the top surface of the flip chip down through the individual conductive legs 70a-70e to selected terminal pads 42 on the grid frame structure 32. The individual terminal pads connected to the conductive legs of the heat sink may in turn be connected to the conductive portion of the printed circuit board on which the package is mounted to further improve the removal of heat from the package.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A grid frame array package comprising:
a grid frame having a selected size and comprising an upper portion with a top surface, an intermediate portion, and a bottom portion, said upper portion defining channels extending from said top surface to said intermediate portion for forming a multiplicity of terminal pads, said channels having a selected width at said top surface and a width greater than said selected width below said top surface;
an electronic chip having a plurality of connecting points electrically connected to selected ones of said terminal pads;
a molding material covering said electronic chip and said grid frame so as to fill said channels defined in said grid frame; and
a multiplicity of singulation grid channels defining a grid in said bottom portion of said grid frame, said grid channels extending from said bottom portion toward said intermediate portion of said grid frame and said grid channels in register with said channels defined in said top surface for providing electrical isolation between said terminal pads.

2. The grid frame array package of claim 1 further comprising an SMD (Surface Mounted Discreet Device) connected between other selected terminal pads.

3. The grid frame array package of claim 1 wherein said electronic chip connecting points are connecting pads on the top side of said chip, further comprising a plurality of conductors electrically connected between said connecting pads and said selected ones of said terminal pads, and wherein said molding material covers said plurality of conductors.

4. The grid frame array package of claim 1 wherein said electronic chip is located on the top surface of said grid frame such that said selected ones of said terminal pads are not covered by said electronic chip.

5. The grid frame array package of claim 4 wherein a portion of said selected ones of said terminal pads are located on all four sides of electronic chip.

6. The grid frame array package of claim 4 wherein at least two rows of said selected ones of said terminal pads are located on said at least two sides of said electronic chip.

7. The grid frame array package of claim 6 wherein at least two rows of said selected ones of said terminal pads are located on all four sides of said electronic chip.

8. The grid frame array package of claim 1 wherein said electronic chip is a flip chip and said connection points are solder bumps and said flip chip is mounted over said selected ones of said terminal pads such that said solder bumps are in electrical contact with said selected terminal pads.

9. The grid frame array package of claim 8 wherein said top surface of at least one of said selected terminal pads defines a divot to receive a corresponding solder bump to facilitate accurate positioning of said electronic flip chip on said grid frame.

10. The grid frame array package of claim 8 wherein said flip chip further comprises a heat conductive layer covering at least a portion of the top side of said flip chip.

11. The grid frame array package of claim 10 further comprising heat conductive legs extending from said heat conductive layer to perimeter ones of said terminal pads for facilitating the removal of heat from said grid frame array package.

12. The grid frame array package of claim 9 wherein a plurality of said selected pads define divots for receiving said solder bumps.

13. The grid frame array package of claim 1 further comprising an inset lead frame bonded to the bottom surface of said electronic chip and the top surface of said base grid frame.

14. The grid frame array package of claim 1 wherein a second electronic chip is mounted on and electrically connected to other selected ones of said terminal pads.

15. A method of fabricating a grid frame array package comprising the steps of:
providing a grid frame having a selected size and including an upper portion with a top surface, an intermediate portion, and a bottom portion;
forming channels in said upper portion of said grid frame said channels extending from said top surface to said intermediate portion and defining a multiplicity of terminal pads, said channels having a selected width at said top surface and a width greater than said selected width below said top surface;
locating an electronic chip having a plurality of connecting points on said grid frame;
electrically connecting said connecting points to selected ones of said terminal pads;
encapsulating said electronic chip and said grid frame with a molding material so as to fill said channels formed in said grid frame; and
forming a multiplicity of singulation channels defining a grid in said bottom portion of said grid frame, said grid channels extending from said bottom portion of said grid frame toward said intermediate portion and in register with said channels formed in said top portion to electrically isolate said terminal pads.

16. The method of claim 15 and further comprising the step of connecting an SMD (Surface Mounted Discreet Device) between two of said terminal pads other than said selected ones of said terminal pads.

17. The method of claim 15 and further comprising the step of forming connecting pads on the top side of said electronic chip as said connecting points and electrically connecting a plurality of conductors between said connecting pads and said selected ones of said terminal pads prior to said covering step such that said plurality of conductors are encapsulated.

18. The method of claim 17 wherein said electronic chip is rectangular shaped and further comprising locating said electronic chip on said grid frame so that a portion of said selected ones of said terminal pads are on at least two sides of said electronic chip.

19. The method of claim 18 and further comprising the step of locating said chip so that a portion of said selected ones of said terminal pads are on four sides of said electronic chip.

20. The method of claim 19 wherein at least two rows of said selected ones of said terminal pads are on said four sides of said electronic chip.

21. The method of claim 15 and further comprising the step of forming solder bumps as said connecting points on said electronic chip and wherein said step of locating the electronic chip comprises the step of locating said solder bumps over said selected ones of said terminal pads such that said solder bumps are in electrical contact with said selected terminal pads.

22. The method of claim 21 and further comprising the step of forming a divot in the top surface of at least one of said selected ones of said terminal pads to receive a corresponding solder bump so as to facilitate accurate positioning of said electronic chip on said grid frame.

23. The method of claim 21 and further comprising the step of covering at least a portion of the top surface of said electronic chip with a heat conductive layer and providing heat conductive legs extending from said heat conductive layer to perimeter ones of said terminal pads for facilitating the removal of heat from said grid frame array package.

24. The method of claim 15 wherein said lead frame is formed by separating said grid frame from a grid frame array substrate strip.
